(19) United States
(12) Patent Application Publication
(10) Pub. No.: US 2019/0003047 A1
(43) Pub. Date: Jan. 3, 2019

(54) Vaporizer and Substrate Processing Apparatus

(71) Applicant: Kokusai Electric Corporation, Tokyo (JP)

(72) Inventors: Hideto TATENO, Toyama (JP); Akinori TANAKA, Toyama (JP); Daisuke HARA, Toyama (JP); Masahisa OKUNO, Toyama (JP); Takuya JODA, Toyama (JP); Takashi TSUKAMOTO, Toyama (JP); Sadayoshi HORII, Toyama (JP); Toru KAKUDA, Toyama (JP)

(21) Appl. No.: 16/125,336

(22) Filed: Sep. 7, 2018

Related U.S. Application Data
(63) Continuation of application No. PCT/JP2016/059415, filed on Mar. 24, 2016.

(51) Int. Cl. C23C 16/448; C23C 16/455; H01L 21/02

(52) U.S. Cl. CPC C23C 16/4485; C23C 16/45563; H01L 21/02337; H01L 21/02123; H01L 21/02222

(57) ABSTRACT

Described herein is a technique capable of preventing an occurrence of the metal contamination in a vaporizer for vaporizing a liquid source. According to the technique described herein, there is provided a vaporizer including: a vaporization vessel constituted by a quartz body; and an atomizer made of a fluorine resin and configured to atomize a liquid source using a carrier gas (atomization gas) and to supply the atomized liquid source into the vaporization vessel.

### CROSS REFERENCE TO RELATED APPLICATIONS

This application is a continuation of International Application No. PCT/JP2016/059415, filed on Mar. 24, 2016, the entire contents of which are hereby incorporated by reference.

### TECHNICAL FIELD

The present disclosure relates to a vaporizer and a substrate processing apparatus.

### BACKGROUND

As a method of separating devices in a Large Scale Integrated Circuit (hereinafter referred to as a “LSI”), voids such as grooves or holes are formed between the devices to be separated on a substrate made of silicon (Si), and an insulating material is deposited in the voids. For example, a silicon oxide film (hereinafter, also referred to as a “SiO film”) may be used as the insulating material. The SiO film may be formed by an oxidation of the silicon substrate itself, a chemical vapor deposition (CVD) method or a Spin-On-Dielectric (SOD) method.

Recently, as the insulating material to be coated in the SOD method, polysilazane (SiH₂NH) (or perhydropolysilazane (PHPS)) is considered. The polysilazane is coated on the substrate using a spin coater to form a film (also referred to as a “coating film”).

Polysilazane contains impurities such as nitrogen (N) from ammonia used in the manufacturing process thereof. Therefore, in order to remove impurities from the coating film (also referred to as a “polysilazane film”) and to obtain a dense SiO film, it is necessary to perform a modification process to the coating film after the coating film is formed by coating the polysilazane. As a method of obtaining the dense SiO film from the polysilazane film, for example, the polysilazane film is modified by supplying a gas containing hydrogen peroxide (H₂O₂) to the polysilazane film.

Instead of filling the voids with the insulating material via the CVD method, the voids may be filled with the insulating material via a flowable CVD method. In the CVD method, and the same method described above is used for the modification process to obtain the dense SiO film.

As a method of generating a gas containing H₂O₂, a vaporized gas containing H₂O₂ can be obtained by vaporizing a liquid source containing H₂O₂ by a vaporizer. From the viewpoint of vaporization efficiency, in general, the vaporizer is made of a metal having a good thermal conductivity. However, H₂O₂ is a highly reactive compound and has the property of corroding most metals. Therefore, when the liquid source containing H₂O₂ is vaporized using the vaporizer, the metal in contact with the liquid source is corroded. Particularly, since the heated part of the vaporizer in contact with the liquid source is at a high temperature, the corrosion of the metal used in the heated part becomes remarkable. Therefore, when the vaporizer described above is used, the occurrence of metal contamination due to the corrosion of the metal is unavoidable. Particularly, in the manufacturing processes of semiconductor devices, it is extremely important to prevent the occurrence of the metal contamination.

### SUMMARY

Described herein is a technique capable of preventing metal contamination in a vaporizer for vaporizing a liquid source.

According to one aspect of the technique described herein, there is provided a vaporizer including: a vaporization vessel constituted by a quartz body; and an atomizer made of a fluorine resin and configured to atomize a liquid source using a carrier gas (atomization gas) and to supply the liquid source into the vaporization vessel.

### BRIEF DESCRIPTION OF THE DRAWINGS

FIG. 1 schematically illustrates a vertical cross-section of a substrate processing apparatus according to an embodiment described herein.

FIG. 2 schematically illustrates a vertical cross-section of a process furnace of the substrate processing apparatus according to the embodiment.

FIG. 3 schematically illustrates a vertical cross-section of a vaporizer of the substrate processing apparatus according to the embodiment.

FIG. 4 schematically illustrates a vertical cross-section of a vaporizing part of the vaporizer according to the embodiment.

FIG. 5 schematically illustrates a vertical cross-section of an atomizing part of the vaporizer according to the embodiment.

FIG. 6 schematically illustrates a configuration of a controller of the substrate processing apparatus and peripherals thereof according to the embodiment.

FIG. 7 is a flowchart illustrating a pre-processing performed before a substrate processing according to the embodiment.

FIG. 8 is a flowchart illustrating the substrate processing according to the embodiment.

### DETAILED DESCRIPTION

### Embodiment

Hereafter, an embodiment will be described with reference to the drawings.

### (1) Configuration of Substrate Processing Apparatus

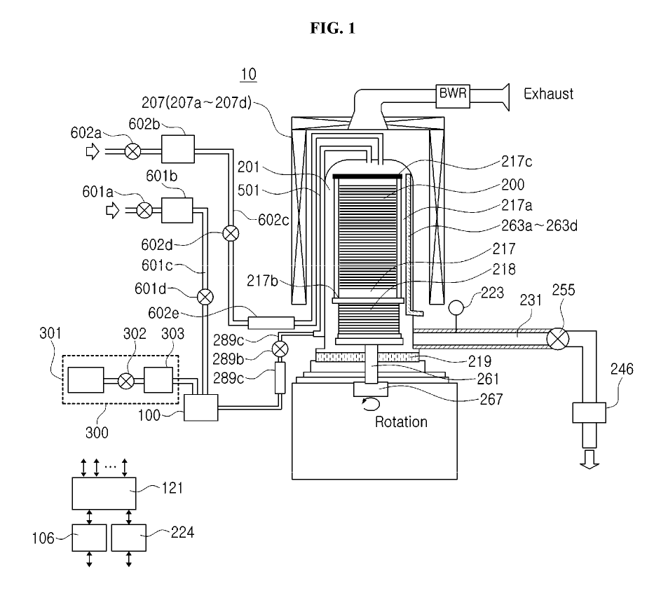

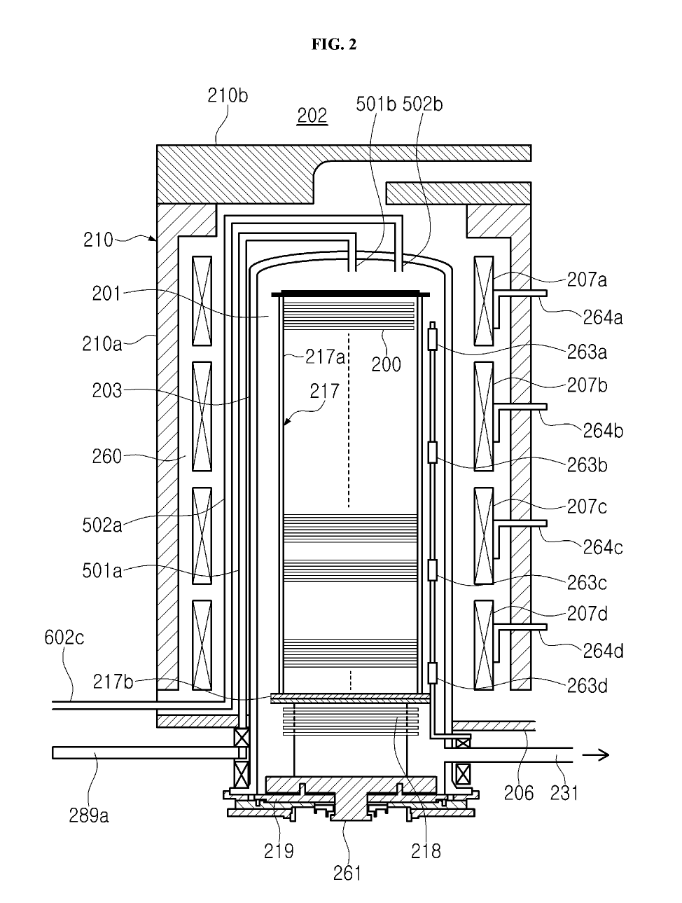

First, an example configuration of a substrate processing apparatus 10 in which a method of manufacturing a semiconductor device according to the embodiment is performed will be described with reference to FIGS. 1 and 2. The substrate processing apparatus 10 is an apparatus for processing a wafer 200 such as a silicon substrate using a process gas generated by vaporizing a liquid source containing hydrogen peroxide (H₂O₂), that is, a hydrogen peroxide solution. Preferably, the substrate processing apparatus 10 is capable of processing the wafer 200 having a concave-convex microstructure such as grooves. According to the embodiment, an oxide film (SiO film) is formed by filling the grooves of the microstructure with a polysilazane film serving a silicon-containing film, and processing the polysilazane film with the process gas. While the embodiment will be described by way of an example in which the polysilazane film is processed by the process gas, the technique described herein is not limited to the polysilazane film. The techniques described herein may also be applied, for example, to the treatment of films including silicon (Si), nitrogen (N) and hydrogen (H), particularly films containing silazane bonds and plasma polymerized films of tetrasilylamine and ammonia.

According to the embodiment, a reactant H₂O₂ vaporized or converted to be in mist state (i.e., H₂O₂ in the gaseous phase) is referred to as a “H₂O₂ gas”, and a gas containing at least the H₂O₂ gas is referred to as a “process gas.” An aqueous solution of H₂O₂ is referred to as a “hydrogen peroxide solution” or a “liquid source.”

### Process Vessel

As shown in FIG. 1, a process furnace 202 includes a process vessel (reaction tube) 203. The process vessel 203 is made of a heat-resistant material such as quartz and silicon carbide (SiC), and is cylindrical with an open lower end. A process chamber 201 is provided in the hollow cylindrical portion of the process vessel 203. The process chamber 201 is capable of accommodating wafers 200 serving as substrates charged in a boat 217 which will be described later. The boat 217 supports concentrically arranged in vertical direction and horizontally oriented wafers 200.

A seal cap 219, which is a furnace opening cover capable of airtightly sealing a lower end opening (furnace opening) of the process vessel 203, is provided under the process vessel 203. The seal cap 219 is provided under the process vessel 203 and is in contact with a lower end of the process vessel 203. The seal cap 219 is disk-shaped. The process chamber 201, which is a processing space where the substrates are processed, is defined by the process vessel 203 and the seal cap 219.

### Substrate Retainer

The boat 217, which is a substrate retainer, supports concentrically arranged wafers 200 in vertical direction while each of the wafers 200 are in horizontal orientation. The boat 217 includes a plurality of support columns 217a supporting the wafers 200. The number of the support columns 217a may be three, for example. The support columns 217a are provided between a bottom plate 217b and a top plate 217c. The support columns 217a support the concentrically arranged wafers 200 in multiple stages along the axis of the process vessel 203. For example, the plurality of support columns 217a, the bottom plate 217b and the top plate 217c are made of a non-metallic material having a high thermal conductivity such as silicon carbide, aluminum oxide (AlO), aluminum nitride (AlN), silicon nitride (SiN) and zirconium oxide (ZrO).

An insulating body 218 is made of a heat-resistant material such as quartz and silicon carbide, and is provided under the boat 217. The insulating body 218 prevents heat radiated from a first heater 207 from reaching the seal cap 219. The insulating body 218 functions as a support body for supporting the boat 217 as well as an insulating part.

### Elevating Mechanism

A boat elevator (not shown) is provided under the process vessel 203. The boat elevator is an elevating mechanism that loads the boat 217 into the process vessel 203 and unloads the boat 217 out of the process vessel 203 by elevating and lowering the boat 217, respectively. When the boat 217 is elevated by the boat elevator, the seal cap 219 then airtightly closes the furnace opening.

A boat rotating mechanism 267 capable of rotating the boat 217 is provided at the seal cap 219 opposite to the process chamber 201. A rotating shaft 261 of the boat rotating mechanism 267 is coupled to the boat 217 through the seal cap 219. As the boat rotating mechanism 267 rotates the boat 217, the wafers 200 are rotated.

### First Heater

A first heater 207 is provided outside the process vessel 203 and concentrically arranged with the process vessel 203. The first heater 207 is capable of heating the wafers 200 accommodated in the process vessel 203. The first heater 207 is supported by a heater base 206. As shown in FIG. 2, the first heater 207 includes a first heating part 207a, a second heating part 207b, a third heating part 207c and a fourth heating part 207d. The first heating part 207a through the fourth heating part 207d are provided in the process vessel 203 along the stacking direction of the wafers 200, respectively. A first temperature sensor 263a, a second temperature sensor 263b, a third temperature sensor 263c and a fourth temperature sensors 263d are provided between the process vessel 203 and the boat 217, respectively. The first temperature sensor 263a through the fourth temperature sensor 263d are provided for the first heating part 207a through the fourth heating part 207d, which are heating parts, respectively. The first temperature sensor 263a through the fourth temperature sensor 263d measures the temperature of the wafers 200 or ambient temperature, and each of the first temperature sensor 263a through the fourth temperature sensor 263d includes, for example, a thermocouple.

The first heater 207 and the first temperature sensor 263a through the fourth temperature sensor 263d are electrically connected to a controller 121 which will be described later. The controller 121 controls the energization states of the first heating part 207a through the fourth heating part 207d based on the temperatures measured by the first temperature sensor 263a through the fourth temperature sensor 263d such that the wafers 200 in the process vessel 203 are at a predetermined temperature. In addition, the controller 121 is also capable of independently controlling the energization state or the temperature of each of the first heating part 207a through the fourth heating part 207d. A first external temperature sensor 264a, a second external temperature sensor 264b, a third external temperature sensor 264c and a fourth external temperature sensor 264d may be further provided at the first heating part 207a through the fourth heating part 207d, respectively. The first external temperature sensor 264a through the fourth external temperature sensor 264d measures the temperatures of the first heating part 207a through the fourth heating part 207d, respectively, and each of the first external temperature sensor 264a through the fourth external temperature sensor 264d includes, for example, a thermocouple. The first external temperature sensor 264a through the fourth external temperature sensor 264d are connected to the controller 121 such that the controller 121 is able to monitor the temperature of each of the first heating part 207a through the fourth heating part 207d via the first external temperature sensor 264a through the fourth external temperature sensor 264d.

### Gas Supply Mechanism (Gas Supply System)

As shown in FIGS. 1 and 2, a process gas supply nozzle 501a and an oxygen-containing gas supply nozzle 502a are provided between the process vessel 203 and the first heater 207 along an outer sidewall of the process vessel 203. For example, the process gas supply nozzle 501a and the oxygen-containing gas supply nozzle 502a are made of quartz which has a low thermal conductivity. Tips (downstream ends) of the process gas supply nozzle 501a and the oxygen-containing gas supply nozzle 502a are inserted into the process vessel 203 through a ceiling of the process vessel 203 in airtight manner. A supply hole 501b and a supply hole 502b are provided at the tips of the process gas supply nozzle 501a and the oxygen-containing gas supply nozzle 502a located in the process vessel 203, respectively. The process gas and an oxygen-containing gas are supplied into the process vessel 203 toward the top plate 217c provided at the top of the boat 217 accommodated in the process vessel 203 through the supply hole 501b and the supply hole 502b, respectively.

A gas supply pipe 602c is connected to the upstream end of the oxygen-containing gas supply nozzle 502a. A valve 602a, a mass flow controller (MFC) 602b which is a flow rate controller, a valve 602d and a heater 602e capable of heating the oxygen-containing gas are provided at the gas supply pipe 602c in order from the upstream side to the downstream side of the gas supply pipe 602c. For example, the oxygen-containing gas includes oxygen (O₂) gas, ozone (O₃) gas, nitrous oxide (NO₂) gas and combinations thereof. In the embodiment, for example, the O₂ gas is used as the oxygen-containing gas. The heater 602e is provided to heat the oxygen-containing gas. The heater 602e may assist the heating of the process gas supplied into the process chamber 201 by heating the oxygen-containing gas. In addition, the re-liquefaction of the process gas in the process vessel 203 may be suppressed by heating the oxygen-containing gas.

A downstream end of a process gas supply pipe 289a for supplying the process gas is connected to the upstream end of the process gas supply nozzle 501a. A vaporizer 100, which is a process gas generator capable of generating the process gas by vaporizing the liquid source, and a valve 289b are provided at the process gas supply pipe 289a in order from the upstream side to the downstream side of the process gas supply pipe 289a. According to the embodiment, the gas containing at least H₂O₂ gas is used as the process gas. A pipe heater 289c such as a jacket heater is provided around the process gas supply pipe 289a to heat the process gas supply pipe 289a.

A liquid source supply system (also referred to as a “liquid source supply mechanism”) 300 for supplying the liquid source (for example, a liquid containing hydrogen peroxide in the embodiment) of the process gas to the vaporizer 100 and a carrier gas supply system (also referred to as a “carrier gas supply mechanism”) (not shown) for supplying a carrier gas to the vaporizer 100 are connected to the vaporizer 100. The vaporized gas of the liquid source generated in the vaporizer 100 is delivered (discharged) as the process gas to the process gas supply pipe 289a together with the carrier gas.

The liquid source supply system 300 includes a liquid source supply 301, a valve 302 and a liquid mass flow controller (LMFC) 303 for controlling the flow rate of the liquid source supplied to the vaporizer 100, which are provided in order from the upstream side to the downstream side of the liquid source supply system 300. The carrier gas supply system includes at least a carrier gas supply pipe 601c, a carrier gas valve 601a, an MFC 601b which is a carrier gas flow rate controller and a carrier gas valve 601d. According to the embodiment, the oxygen-containing gas such as O₂ gas may be used as the carrier gas. However, the oxygen-containing gas such as O₃ gas), NO gas, O₂ gas and combinations thereof may be used as the carrier gas. In addition, gases having a low reactivity with the wafers 200 or films formed on the wafers 200 may be used as the carrier gas. For example, nitrogen (N₂) gas or rare gases such as argon (Ar) gas, helium (He) gas and neon (Ne) gas may be used as the carrier gas.

According to the embodiment, the process gas supply nozzle 501a and the supply hole 501b constitute a process gas supply system. The process gas supply system may further include the process gas supply pipe 289a, the valve 289b and the vaporizer 100. The oxygen-containing gas supply nozzle 502a and the supply hole 502b constitute an oxygen-containing gas supply system. The oxygen-containing gas supply system may further include the gas supply pipe 602c, the heater 602e, the valve 602d, the MFC 602b and the valve 602a. The process gas supply system and the oxygen-containing gas supply system constitute a gas supply system (i.e., gas supply mechanism).

### Vaporizer

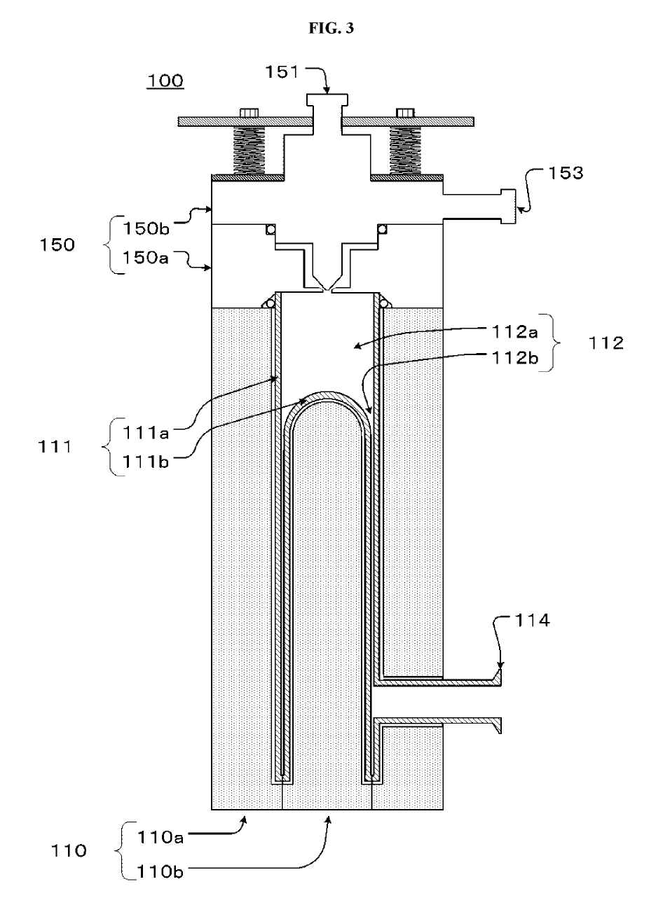

Subsequently, a schematic structure of the vaporizer 100 will be described with reference to FIG. 3. The vaporizer 100 vaporizes the liquid source by supplying fine droplets of the liquid source to a heated vaporizing part 110. The liquid source is atomized into the fine droplets by an atomizing part (also referred to as an “atomizer”) 150.

The vaporizing part 110 is constituted by two blocks, that is, an outer block 110a and an inner block 110b. The inner block 110b serving as a vaporization heat block is inserted into the cylindrical outer block 110a with a cylindrical gap 112b therebetween. The cylindrical gap 112b serves as a cylindrical gas flow path for the vaporized gas. A vaporization space 112 is constituted by an upper space 112a provided above the inner block 110b and the gap 112b provided between the outer block 110a and the inner block 110b. The vaporized gas generated in the vaporization space 112 is discharged (delivered) to the process gas supply pipe 289a as the process gas together with the carrier gas via an exhaust port 114. A vaporization vessel 111 is constituted by a quartz body 111a formed on a surface (i.e. inner surface) of the outer block 110a exposed to the vaporization space 112 and a quartz body 111b formed on a surface of the inner block 110b exposed to the vaporization space 112. That is, the vaporization vessel 111 has a double tube structure including the quartz bodies 111a and 111b.

The atomizing part 150 is constituted by two blocks, that is, a lower block (also referred to as a “first block”) 150b and an upper block (also referred to as a “second block”) 150a. The lower block 150a is provided on an upper portion of the outer block 110a of the vaporizing part 110, and is configured to close an opening portion of the upper space 112a. That is, the atomizing part 150 is connected to the vaporization vessel 111 to close the opening portion of the cylindrical outer block 110a. The upper block 150b is provided on an upper portion of the lower block 150a. The atomizing part 150 is made of a fluorine resin. In the embodiment, the fluorine resin refers to a resin such as PFA, PTFE and PCTFE.

Hereinafter, the structure of the vaporizing part 110 and the atomizing part 150 will be described in detail.

### Vaporizing Part

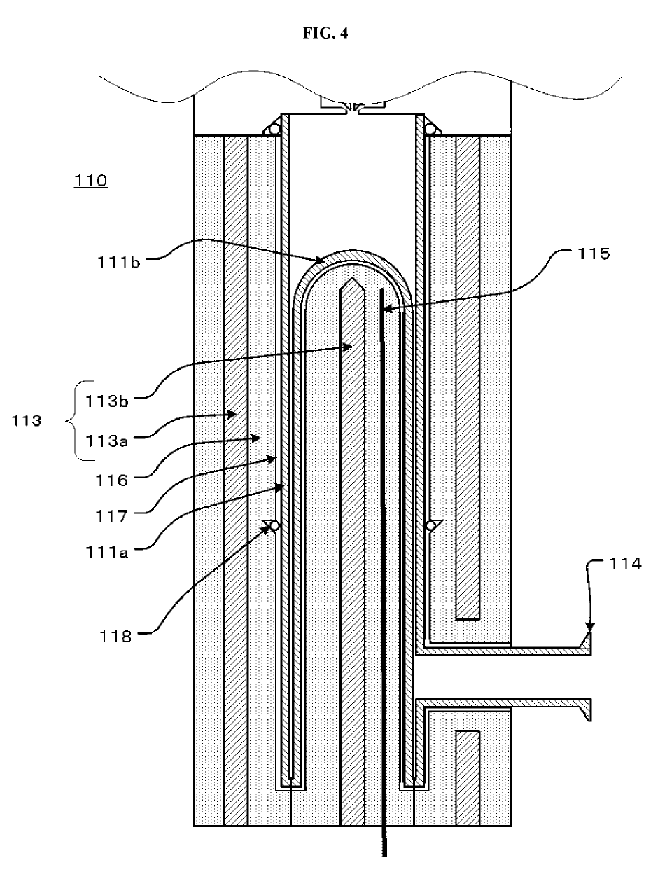

The structure of the vaporizing part 110 will be described in detail with reference to FIG. 4. The vaporizing part 110 includes: the vaporization vessel 111 made of a quartz material such as quartz glass; a vaporization space 112 provided in the vaporization vessel 111; a vaporizer heater 113 serving as a heating mechanism and configured to heat the vaporization vessel 111; the exhaust port 114; and a temperature sensor 115 constituted by a thermocouple and configured to measure the temperature of the vaporization vessel 111. The vaporizer heater 113 is constituted by a heater 113a embedded in the inner block 110a and a heater 113b embedded in the outer block 110b.

The surface of the vaporization vessel 111 exposed to the vaporization space 112, that is, the surface of the vaporization vessel 111 in contact with the liquid source is entirely made of quartz which is a material free of metal. Thus, it possible to prevent the above-described metal contamination from being generated by the reaction between the material constituting the vaporization vessel and the liquid source.

### Configuration of Heater and Peripherals Thereof

The quartz material constituting the vaporization vessel 111 has a low thermal conductivity. Therefore, in comparison with a vaporization vessel made of metal, it is difficult to transfer the heat from the heater to the liquid source and to vaporize the liquid source with the vaporization vessel 111. According to the embodiment, a metal block 116 is inserted between the vaporizer heater 113 and the vaporization vessel 111 in order to transfer the heat generated from the vaporizer heater 113 to the quartz material of the vaporization vessel 111. According to the embodiment, the metal block 116 is made of aluminum (Al). The quartz material has a lower thermal conductivity than that of the metal. However, by inserting the metal block 116 of highly thermally conductive metal, it is possible to uniformly transfer the heat from the vaporizer heater 113 to the vaporization vessel 111

A heat transfer paste 117 is applied between the vaporizer heater 113 and the metal block 116 and between the metal block 116 and the vaporization vessel 111. Since the heat transfer paste 117 is filled in gaps between the vaporizer heater 113 and the metal block 116 and between the metal block 116 and the vaporization vessel 111, it is possible to remove the gaps described above and to transfer the heat more uniformly. Particularly, if there is a gap between the metal block 116 and the vaporization vessel 111, a temperature difference may occur in the vaporization vessel 111. Thus, it is effective to apply the heat transfer paste 117 to the gap.

When the heat is not uniformly transferred to the vaporization vessel 111 and the temperature difference occurs, the liquid source may not be vaporized (or re-liquefied) due to a local temperature drop. Thus, it is important to transfer the heat uniformly to the vaporization vessel 111. According to the embodiment, it is possible to uniformly transfer the heat from the vaporizer heater 113 to the vaporization vessel 111. Thereby, it is possible to suppress the temperature difference in the vaporization vessel 111 and to vaporize the liquid source efficiently.

### Double Tube Structure of Vaporization Vessel

In addition, according to the embodiment, the vaporization vessel 111 has the double tube structure as described above in order to more efficiently transfer the heat from the heater such as the vaporizer heater 113 to the liquid source. The droplets of the liquid source supplied from the atomizing part 150 are heated and vaporized by passing through the upper space 112a and the cylindrical gap 112b provided between the outer block 110a and the inner block 110b. The width of the gap 112b is, for example, 0.5 mm to 2 mm. In the embodiment, the width of the gap 112b is 1 mm. By narrowing the gap 112b through which the droplets of the liquid source pass to a predetermined width as described above and by increasing the surface area per unit volume of the droplets of the liquid source (or the carrier gas containing the droplets) contacting the vaporization vessel 111, it is possible to efficiently transfer the heat of the vaporization vessel 111 to the liquid source. From the viewpoint of the vaporization efficiency, it is desirable that the width of the gap 112b is as narrow as possible. However, in practice, it is necessary to set the width of the gap 112b by considering the dimensional accuracy in the production of the vaporization vessel 111 and the minimum width required for ensuring the flow rate of the vaporized gas.

In addition, the upper portion (tip portion) of the inner block 110b is dome-shaped (spherical-shaped). By the dome-shaped upper portion of the inner block 110b, when the droplets of the liquid source supplied to the upper space 112a adhere to the surface of the dome-shaped upper portion of the inner block 110b, the droplets of the liquid source flow in the direction of the gap 112b without staying on the surface in a liquid state. Thus, it is possible to prevent the temperature of the surface of the dome-shaped upper portion from locally decreasing and to improve the vaporization efficiency.

The temperature data measured by the temperature sensor 115 is output to a temperature controller 106, and the temperature controller 106 controls the temperature of the vaporizer heater 113 based on the temperature data. In the vaporizer 100 according to the embodiment, for example, one temperature sensor 115 is provided near the tip (upper end) of the inner block 110b. However, the embodiment is not limited thereto. A plurality of temperature sensors may be provided in other locations. For example, the temperature sensors may be provided in at least one location such as the vicinity of the lower end of the inner block 110b, the vicinity between the upper end and the lower end of the inner block 110b, the vicinity of the upper end of the outer block 110a, the vicinity of the lower end of the outer block 110a, and the vicinity between the upper end and the lower end of the outer block 110a. The temperature of the heater 113a of the outer block 110a and the temperature of the heater 113b of the inner block 110b may be individually controlled based on the temperature data measured by the plurality of temperature sensors.

In order to prevent the quartz body 111a from being damaged by direct contact with the metal block 116, an O-ring 118 made of a heat-resistant material such as a heat-resistant fluorine rubber is provided between the metal block 116 of the outer block 110a and the quartz body 111a. The O-ring 118 serves as a spacer. By providing the O-ring 118, it is possible to prevent the contact between the metal block 116 and the quartz body 111a even when the heat transfer paste 117 is deformed by the heat.

In addition, similar to the vaporization vessel 111, the exhaust port 114 is made of the quartz material. A connection interface part of the exhaust port 114 whereat the process gas supply pipe 289a is connected thereto has an NW flange structure. The exhaust port 114 seals the connection interface part with an O-ring (not shown) interposed therebetween. With the above-described connection interface part, it is possible to prevent the process gas and the liquid source from leaking at the connection interface part.

According to the embodiment, the vaporizing part 110 has a structure divided into the outer block 110a and the inner block 110b. However, the embodiment is not limited thereto. For example, the outer block 110a and the inner block 110b may be integrally formed. In addition, the quartz body 111a and the quartz body 111b may be welded together to form the vaporization vessel 111 integrally.

### Atomizing Part (Atomizer)

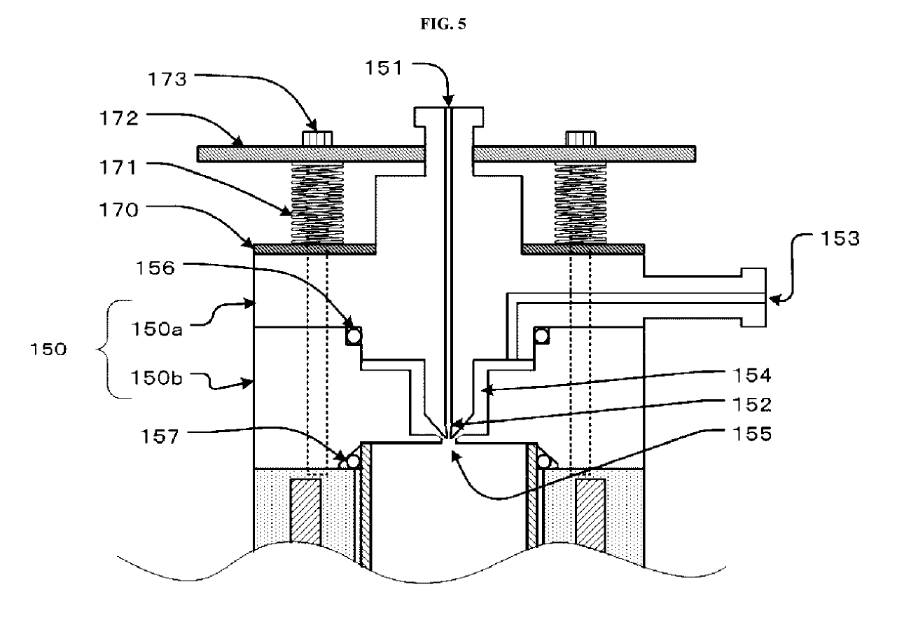

The structure of the atomizing part 110 will be described in detail with reference to FIG. 5. The atomizing part 150 is constituted by two blocks, that is, a lower block 150a and an upper block 150b, which are made of a fluorine resin.

### Upper Block 150b

A liquid source inlet port 151 configured to introduce the liquid source (i.e., the hydrogen peroxide solution) supplied via the LMFC 303, a discharge nozzle 152 configured to discharge the liquid source introduced via the liquid source inlet port 151 into the vaporization vessel 111, and a carrier gas inlet port 153 configured to introduce the carrier gas supplied via the carrier gas supply pipe 601c are provided at the upper block 150b.

### Lower Block 150a

An ejection hole 155 serving as an ejection part configured to eject the carrier gas and the liquid source into the upper space 112a in the vaporization vessel 111 is provided at the lower block 150a.

### Connection Between Lower Block 150a and Upper Block 150b

The lower block 150a and the upper block 150b define a buffer space 154 for the carrier gas by connecting the lower block 150a and the upper block 150. The carrier gas introduced into the carrier gas inlet port 153 is ejected via the ejection hole 155 into the upper space 112a via the buffer space 154. The tip of the discharge nozzle 152 is inserted into the ejection hole 155, whereby a flow path of the carrier gas in the ejection hole 155 is constrained to be narrow. Since the flow of the carrier gas passing through the ejection hole 155 becomes very fast, the droplets of the liquid source discharged via the tip of the discharge nozzle 152 are atomized by the carrier gas. As described above, the liquid source discharged via the discharge nozzle 152 is ejected into the upper space 112a of the vaporization vessel 111 as fine liquid droplets together with the carrier gas.

An O-ring 156 serving as a sealing part is provided at a joint portion between the lower block 150a and the upper block 150b in the vicinity of the buffer space 154 in order to prevent the leakage of the carrier gas. According to the embodiment, a heat-resistant fluorine rubber may be used as the O-ring 156. The sealing part of the embodiment is not limited to an O-ring. For example, a component such as a gasket may be used as the sealing part.

### Connection Between Vaporizer 110 and Lower Block 150a

An O-ring 157 serving as a sealing part is provided at a joint portion where the vaporization vessel 111 (more specifically, the quartz body 111a) and the lower block 150a contact each other in order to prevent the leakage of the vaporized gas and the liquid source. Similar to the O-ring 156, according to the embodiment, a heat-resistant fluorine rubber may be used as the O-ring 157. The sealing part of the embodiment is not limited to an O-ring. For example, a component such as a gasket may be used as the sealing part.

As described above, in the atomizing part 150 according to the embodiment, the portions of the atomizing part 150 where the liquid source and the carrier gas are in contact are all made of a material such as a fluorine resin and a fluorine rubber free of metal (i.e., metal-free material). Therefore, in the atomizing part 150, it is possible to prevent the occurrence of the metal contamination by the reaction of the liquid source and the metal. In particular, it is suitable for vaporizing a highly reactive liquid source such as the hydrogen peroxide solution. Similarly, the surface of the vaporizing part 110 in contact with the liquid source is also made of quartz, which is a metal-free material. Thus, it is possible to prevent the metal contamination caused by the reaction between the material of the vaporization vessel and the liquid source. Therefore, it is possible to completely eliminate the metal contamination in the vaporizer 100 according to the embodiment in both atomization and vaporization steps.

### Creep Prevention Mechanism

In general, a synthetic resin containing the fluorine resin deforms due to a creeping phenomenon when pressed. Especially, the synthetic resin deforms remarkably at a high temperature. According to the embodiment, the atomizing part 150 made of the fluorine resin is connected to the heated vaporizing part 110, and the temperature of the atomizing part 150 rises with time. Thus, the atomizing part 150 deforms due to the creep phenomenon. Therefore, even when there is no looseness at joint portions such as the joint portion between the vaporization vessel 111 and the lower block 150a and the joint portion between the lower block 150a and the upper block 150b before the vaporizing part 110 is heated, the joint portions may become loose as the vaporizing part 110 is heated. As a result, gaps may be formed therebetween. Thereby, the leakage of the vaporized gas and the carrier gas or the leakage of liquid source may occur via the gaps. In particular, the vaporizer 100 according to the embodiment has a structure that the vaporization vessel 111 made of quartz and the lower block 150a made of the fluorine resin are joined. The quartz is hardly deformed compared with the fluorine resin even in a high temperature state. Thus, according to the embodiment, the gaps tend to be formed easily due to the creep phenomenon.

In order to address the above-described problem, according to the embodiment, the vaporizer 100 is provided with a creep prevention mechanism capable of constantly pressing the atomizing part 150 to the vaporizing part 110 with a constant pressing pressure. Thus, it is possible to prevent the gas leakage and the liquid leakage caused by the creep phenomenon due to the atomizing part 150 made of the fluorine resin.

The creep prevention mechanism includes a pressing plate 170, a spring 171 serving as an elastic body, a fixing plate 172 and a holding screw 173 such as a bolt. The pressing plate 170 is a plate provided on the upper surface of the upper block 150b and configured to press the upper block 150b from above. The spring 171 is provided on the upper surface of the pressing plate 170 and is an elastic body that presses the pressing plate 170 between the fixing plate 172 and the pressing plate 170. The fixing plate 172 is configured to fix a relative distance between the fixing plate 172 and the vaporizing part 110. According to the embodiment, the holding screw 173 penetrates the fixing plate 172, the spring 171, the upper block 150b and the lower block 150a, and is provided to be coupled to the metal block 116 of the vaporizing part 110. By coupling the holding screw 173 to the metal block 116, the distance between the fixing plate 172 and the vaporizing part 110 is fixed. In addition, it is possible to adjust the distance by adjusting the degree of tightening of the holding screw 173.

The fixing plate 172 fixed by the holding screw 173 is configured to press the spring 171 against the pressing plate 170. Therefore, due to the elastic force of the spring 171, a constant pressing pressure is applied to the lower block 150a and the upper block 150b toward the vaporizing part 110 by the pressing plate 170.

The elastic body pressing the pressing plate 170 is not limited to the spring. For example, it is possible to select an appropriate elastic body such as a plate spring or rubber. In addition, instead of using the holding screw 173, it is also possible to adopt a structure in which the distance between the vaporizing part 110 and the fixing plate 172 is fixed and adjusted by a fixing mechanism such as a clamp mechanism.

According to the embodiment, the vaporizing part 110, the lower block 150a and the upper block 150b are always pressed against one another with a constant pressing pressure by the creep prevention mechanism. Thus, even when at least one of the lower block 150a and the upper block 150b is deformed by the creep phenomenon, it is possible to prevent the occurrence of the gaps due to the loosening of the joint portions. In particular, it is possible to effectively prevent the gas leakage and the liquid leakage via the joint portion between the vaporization vessel 111 and the lower block 150a, in which the gap is likely to occur due to the creep phenomenon.

As another method for preventing the occurrence of the gaps of the joint portions, it is also possible to adopt a structure in which the vaporizing part 110, the lower block 150a and the upper block 150b are pressed by components such as screws and clamps without using an elastic body such as the spring. However, according to the another method, it is required to apply a high pressing pressure before heating the vaporizing part 110 in consideration of the amount of deformation due to the creep phenomenon. Thus, on the contrary, there is a possibility of promoting the creep phenomenon. In addition, when the amount of deformation exceeds a certain amount, the pressing pressure cannot be applied so that it is impossible to prevent the occurrence of the gaps at the joint portions. The creep prevention mechanism according to the embodiment is suitable as a structure for preventing the occurrence of the gaps at the joint portions because it can always press with a constant pressing pressure even if the deformation progresses by using the elastic body such as the spring.

According to the embodiment, the vaporizing part 110 and the lower block 150a and the upper block 150b of the atomizing part are divided, respectively, and are fixed so as to be pressed against one another by the creep prevention mechanism. Therefore, it is possible to easily disassemble the vaporizer 100 into each block only by removing the spring 171 and the holding screw 173, and it is also excellent in maintainability such as the cleaning of the vaporizer 100.

The embodiment is not limited to the structure such as the creep prevention mechanism. For example, the vaporizing part 110 and the lower block 150a and the upper block 150b of the atomizing part 150 are constantly pressed against one another at a constant pressing pressure by using an elastic force of an elastic body such as a spring. For example, while the vaporizer 100 is fixed, the upper block 150b may be pressed in the direction of the vaporizing part 110 by an elastic body such as a spring fixed outside the vaporizer 100. For example, while the upper block 150b is fixed, the vaporizing part 110 may be pressed in the direction of the upper block 150b by an elastic body such as a spring provided under the vaporizing part 110. Although the atomizing part 150 is divided into the lower block 150a and the upper block 150b according to the embodiment, it is also possible to apply the above-described creep prevention mechanism even when the atomizing part 150 is integrally constructed. That is, the creep preventing mechanism causes the atomizing part 150 and the vaporizing part 110 to constantly press each other with a constant pressing pressure.

### Exhaust System

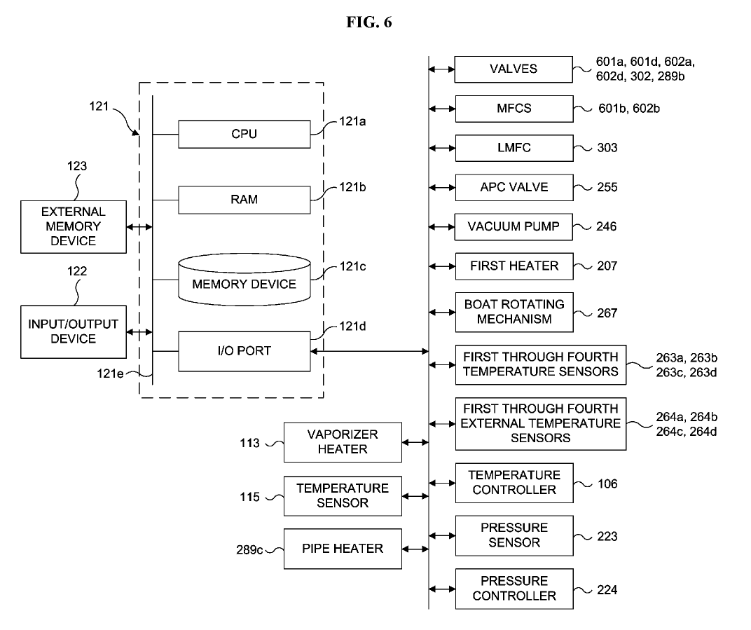

One end of a gas exhaust pipe 231 for exhausting the inner atmosphere of the process chamber 201 is connected to the lower sidewall of the process vessel 203. A vacuum pump 246, which is a vacuum exhausting device, is connected to the other end of the gas exhaust pipe 231 via an APC (Automatic Pressure Controller) valve 255 which is a pressure controlling device. The inner atmosphere of the process chamber 201 is exhausted by way of generating a negative pressure by the vacuum pump 246. A pressure sensor 223, which is a pressure detector, is provided at the upstream side of the APC valve 255. The inner atmosphere of the process chamber 201 may be exhausted by using above-described components such that an inner pressure of the process chamber 201 is at a predetermined pressure (vacuum level). A pressure controller 224 shown in FIG. 6 is electrically connected to the pressure sensor 223 and the APC valve 255. The pressure controller 224 controls the operation of the APC valve 255 such that the inner pressure of the process chamber 201 is adjusted to a desired level at a desired timing based on the pressure detected by the pressure sensor 223.

The gas exhaust pipe 231 and the APC valve 255 constitute an exhaust system. The exhaust system may further include the pressure sensor 223. The exhaust system may further include the vacuum pump 246.

### Controller

As shown in FIG. 6, the controller 121, which is a control device (control mechanism), is embodied by a computer having a CPU (Central Processing Unit) 121a, a RAM (Random Access Memory) 121b, a memory device 121c and an I/O port 121d. The RAM 121b, the memory device 121c and the I/O port 121d may exchange data with the CPU 121a via an internal bus 121e. An input/output device 121 such as a touch panel and a display device may be connected to the controller 121.

The memory device 121c may be embodied by components such as flash memory and HDD (Hard Disk Drive). A control program for controlling the operation of the substrate processing apparatus 10 and a process recipe in which information such as the sequence and condition of the substrate processing which will be described later is stored are readably stored in the memory device 121c. The process recipe is a program that is executed in the controller 121 to obtain a predetermined result by performing sequences of the substrate processing. Hereinafter, the process recipe and the control program are collectively referred to simply as a program. The process recipe is also referred to simply as a recipe. The term “program” may refer to only the process recipe, only the control program, or both. The RAM 121b is a work area in which the program or the data read by the CPU 121a are temporarily stored.

The I/O port 121d is electrically connected to the components such as the LMFC 303, the MFCs 601b and 602b, the valves 601a, 601d, 602a, 602d, 302 and 289b, the APC valve 255, the first heater 207 (the first heating part 207a through the fourth heating part 207d), the first temperature sensor 263a through the fourth temperature sensor 263d, the boat rotating mechanism 267, the pressure sensor 223, the temperature controller 106, the vaporizer heater 113, the temperature sensor 115 and the pipe heater 289c.

The CPU 121a is configured to read and execute the control program stored in the memory device 121c, and read the recipe stored in the memory device 121c in accordance with an instruction such as an operation command inputted via the input/output device 122. The CPU 260a may be configured to control operation of the substrate processing apparatus 10 according to the recipe. For example, the CPU 260a may be configured to perform operation such as a flow rate adjusting operation of the LMFC 303 for the liquid source, flow rate adjusting operations of the MFCs 601a and 601b for various gases, opening/closing operations of the valves 601a, 601d, 602a, 602d, 302 and 289b, an opening/closing operation of the APC valve 255, a temperature adjusting operation of the first heater 207 based on the temperatures measured by the first temperature sensor 263a through the fourth temperature sensor 263d, a start and stop of the vacuum pump 246, a rotation speed adjusting operation of the boat rotating mechanism 267, a temperature adjusting operation of the vaporizer heater 113 via the temperature controller 106, and a temperature adjusting operation of the pipe heater 289c via the temperature controller 106.

The controller 121 may be embodied by installing the above-described program stored in an external memory device 123 to a computer. The external memory device 123 may include a magnetic tape, a magnetic disk such as a flexible disk and a hard disk, an optical disk such as CD and DVD, a magneto-optical disk such as MO, and a semiconductor memory such as a USB memory and a memory card. The memory device 121c or the external memory device 123 may be embodied by a non-transitory computer readable recording medium. Hereafter, the memory device 121c and the external memory device 123 are collectively referred to as recording media. In the specification, “recording media” may refer to only the memory device 121c, only the external memory device 123, or both. In addition to the external memory device 123, a communication network such as the Internet and dedicated line may be used as the means for providing the program to the computer.

### (2) Pre-Processing

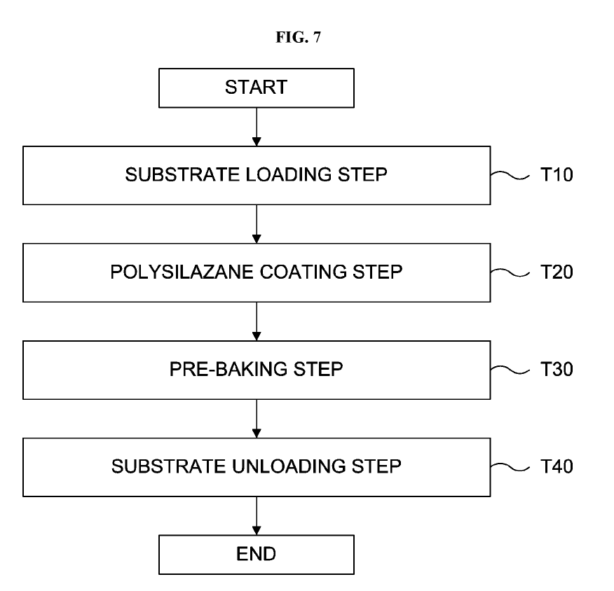

Hereinafter, a pre-processing performed before a modifying step of the wafer 200 serving as the substrate will be described with reference to FIG. 7. As shown in FIG. 7, the pre-processing includes: a polysilazane coating step T20 wherein polysilazane is coated on the wafer 200; and a pre-baking step T30. According to the polysilazane coating step T20, the polysilazane is applied by a coating device such as a spin coater (not shown). The thickness of the coated polysilazane is determined by the conditions such as the molecular weight of the polysilazane, the viscosity of the polysilazane solution and the number of rotations of the spin coater. According to the pre-baking step T30, the solvent is removed from the polysilazane coated on the wafer 200. Specifically, the solvent is volatilized by heating the polysilazane coated on the wafer 200 to a temperature of from about 70° C. to 250° C. Preferably, the polysilazane coated on the wafer 200 is heated to about 150° C.

The wafer 200 used in the pre-processing has the concave-convex microstructure described above. The applied polysilazane fills at least the grooves of the concave-convex structure. That is, a polysilazane coating film, which is a silicon-containing film, is formed in the grooves of the wafer (substrate) 200. Hereinafter, an example wherein the gas containing H₂O₂, which is obtained by vaporizing the hydrogen peroxide solution, is used as the process gas will be described. In the embodiment, the silicon-containing film may refer a film containing, for example, silicon, nitrogen and hydrogen. The silicon-containing film may also contain carbon or other impurities.

In the pre-processing according to the embodiment, the wafer 200 is loaded into a processing apparatus (not shown) which is different from the substrate processing apparatus 10 described above (a substrate loading step, T10), and the polysilazane coating step T20 and the pre-baking step T30 are performed in the processing apparatus. After the polysilazane coating step T20 and the pre-baking step T30 are completed, the wafer 200 is unloaded from the processing apparatus (substrate unloading step, T40).

### (3) Substrate Processing

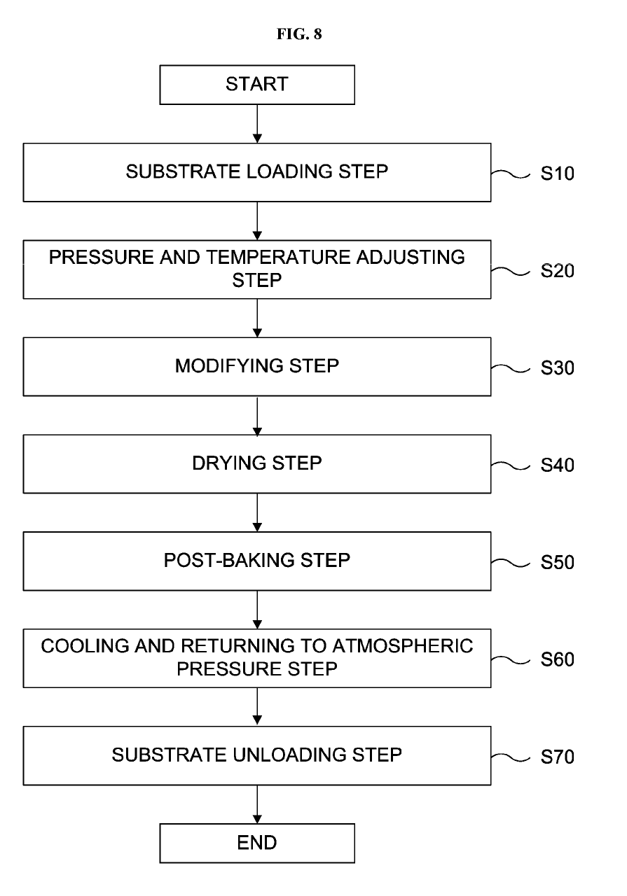

Hereinafter, an exemplary sequence of the substrate processing, which is one of the processes of manufacturing a semiconductor device, will be described with reference to FIG. 8. The substrate processing is performed by using the substrate processing apparatus 10. In the embodiment, as an example of the substrate processing according to the embodiment, a modifying step (oxidation step) wherein a silicon-containing film formed on the wafer (substrate) 200 is modified (oxidized) into an SiO film using the process gas containing H₂O₂ will be described. Herein, the components of the substrate processing apparatus 10 are controlled by the controller 121.

### Substrate Loading Step S10

First, a predetermined number of wafers 200 are charged into the boat 217 (wafer charging). The boat 217 accommodating the wafers 200 is elevated by the boat elevator (not shown) and loaded into the process vessel 203 (boat loading). With the boat 217 loaded, the seal cap 219 seals the lower end opening (furnace opening) of the process furnace 202.

### Pressure and Temperature Adjusting Step S20

The vacuum pump 246 vacuum-exhausts the process vessel 203 such that the inner pressure of the process vessel 203 is adjusted to a desired pressure (vacuum level). The oxygen-containing gas is supplied into the process vessel 203 via the supply hole 502b of the oxygen-containing gas supply system. Preferably, the oxygen-containing gas is supplied into the process vessel 203 after being heated to a temperature ranging from 100° C. to 120° C. by the heater 602e. In the pressure and temperature adjusting step S20, the inner pressure of the process vessel 203 is measured by the pressure sensor 223, and the opening degree of the APC valve 255 is feedback-controlled based on the measured pressure (pressure adjusting). Preferably, the inner pressure of the process vessel 203 is adjusted such that the process vessel 203 is not depressurized, for example, to a pressure ranging from 700 hPa to 1,000 hPa.

The first heater 207 heats the process vessel 203 such that the temperature of the wafers 200 in the process vessel 203 is adjusted to a desired first temperature ranging from 40° C. to 100° C., for example. The energization states of the first heating part 207a through the fourth heating part 207d of the first heater 207 are feedback-controlled based on the temperature measured by the first temperature sensor 263a through the fourth temperature sensor 263d, respectively, such that the wafers 200 in the process vessel 203 are at the first temperature (temperature adjusting). The first heating part 207a through the fourth heating part 207d are controlled such that the temperatures of the first heating part 207a through the fourth heating part 207d are the same.

The boat rotating mechanism 267 starts to rotate the boat 217 and the wafers 200 while the wafers 200 are heated. The rotation speed of the boat 217 is controlled by the controller 121. The boat rotating mechanism 267 continuously rotates the boat 217 until at least a modifying step S30, which will be described later, is completed.

### Modifying Step S30

When the wafer 200 is heated to the first temperature and the boat 217 is rotated at a predetermined speed, the liquid source (for example, the hydrogen peroxide solution) is supplied to the vaporizer 100 by the liquid source supply system 300. Specifically, the valve 302 is opened to supply the liquid source to the atomizing part 150 via the liquid source inlet port 151. The flow rate of the liquid source is adjusted by the LMFC 303 when the liquid source is supplied to the atomizing part 150. The liquid source supplied to the atomizing part 150 is atomized by the carrier gas passing through the ejection hole 155 when the liquid source is discharged through the discharge nozzle 152, and is sprayed into the upper space 112a in the vaporization vessel 111 as fine liquid droplets (for example, in a mist state). The vaporization vessel 111 made of quartz is heated to a desired temperature (for example, 180° C. to 220° C.) by the vaporizer heater 113 via the metal block 116, and the droplets of the sprayed liquid source (the hydrogen peroxide solution) are heated and vaporized in the surface of the vaporization vessel 101 or in the vaporization space 112. Thereby, the droplets are transformed into a gas state. According to the vaporizer 100 of the embodiment, particularly, the droplets of the liquid source are efficiently vaporized by passing through the gap 112b. The vaporized liquid source is delivered as the process gas (vaporized gas) together with the carrier gas via the exhaust port 114 to the process gas supply pipe 289a.

The temperature of the vaporizer heater 113 is adjusted based on the temperature data measured by the temperature sensor 115 in order to avoid the vaporization failure. When a liquid source in the droplet state (or mist state) is contained in the process gas supplied into the process chamber 201 due to the vaporization failure, for example, particles are generated during the modifying step. Thus, the quality of the SiO film may deteriorate. When the temperature of at least a portion of the vaporization vessel 111 is decreased, the droplet may not be completely vaporized or may be re-liquefied. Thus, the temperature of the vaporizer heater 113 is adjusted to be equal to or higher than the predetermined temperature such that the droplets are completely vaporized and not re-liquefied.

The process gas, which is the gas delivered from the vaporizer 100, is supplied into the process chamber 201 by opening the valve 289b via the process gas supply pipe 289a, the valve 289b, the process gas supply nozzle 501a and the supply hole 501b. The process gas introduced into the process chamber 201 via the supply hole 501b is supplied to the wafer 200. The H₂O₂ gas contained in the process gas acts as a reactive gas. The H₂O₂ gas contained in the process gas reacts with the silicon-containing film on the wafer 200 to modify (oxidize) the silicon-containing film, thereby forming the SiO film.

While the process gas is supplied into the process vessel 203, the inner atmosphere of the process vessel 203 is exhausted by the vacuum pump 246. Specifically, the APC valve 255 is opened and the vacuum pump 246 is operated, and the gas exhausted from the process vessel 203 flows through the gas exhaust pipe 231. After a predetermined time, the valve 289b is closed and the supply of the process gas into the process vessel 203 is stopped. After another predetermined time, the APC valve 255 is closed and the exhaust of the inner atmosphere of the process vessel 203 is stopped.

While the embodiment is described by way of an example wherein the hydrogen peroxide solution is supplied to the vaporizer 100 as the liquid source and the process gas containing H₂O₂ is supplied into the process vessel 203, the embodiment is not limited thereto. For example, a liquid including ozone (O₃) and a liquid such as water (H₂O) may be used as the liquid source in the embodiment. However, when the liquid source containing a highly reactive compound such as H₂O₂ used in the embodiment is vaporized, it is particularly preferable to use the vaporizer 100 according to the embodiment which is configured to prevent the contact between the liquid source and the metal which causes the metal contamination.

### Drying Step S40

After the modifying step S30 is completed, the temperature of the wafer 200 is elevated to a predetermined second temperature. The second temperature is higher than the first temperature which is described above, and is equal to or lower than the temperature of the pre-baking step T30. The second temperature is, for example, 150° C. After the temperature of the wafer 200 is elevated to the second temperature, the wafer 200 and the inside of the process vessel 203 are gradually dried while maintaining the second temperature. As a result, by-products such as ammonia, ammonium chloride, carbon and hydrogen, which are desorbed from the polysilazane film, impurities such as gas from the solvent, and impurities from the H₂O₂ are prevented from reattaching to the wafer 200 while drying the wafer 200.

### Post-Baking Step S50

After the drying step S40 is completed, the temperature of the wafer 200 is elevated to a temperature higher than the second temperature of the drying step S40 under an atmosphere containing at least one of nitrogen, oxygen and argon to remove hydrogen remaining in the SiO film. As a result, a high quality SiO film with low hydrogen content is obtained. By performing the post-baking step S50, the SiO film with improved quality can be obtained for a device manufacturing process requiring a high quality oxide film such as STI. The post-baking step S50 may be omitted in device manufacturing processes requiring a high quality oxide film when the manufacturing throughput is prioritized.

### Cooling and Returning to Atmospheric Pressure Step S60

After the drying step S40 or the post-baking step S50 are completed, the particles or impurities remaining in the process vessel 203 are removed by opening the APC valve 255 and vacuum-exhausting the process vessel 203. After the vacuum-exhaust, the APC valve 255 is closed and the inner pressure of the process vessel 203 is returned to an atmospheric pressure. Thereafter, the wafer 200 and the process vessel 203 are heated to remove the particles and impurities still remaining after the vacuum exhaust, the gas desorbed from the wafer 200 and the residual impurities contained in the hydrogen peroxide solution. It is preferable to heat the wafer 200 and the process vessel 203 under atmospheric pressure because the heat capacity of the process vessel 203 is increased and the wafer 200 and the process vessel 203 are more uniformly heated. After the inner pressure of the process vessel 203 is returned to the atmospheric pressure and a predetermined time has elapsed, the temperature of wafer 200 is lowered until a predetermined temperature (e.g., a temperature at which the wafer can be unloaded) is reached.

### Substrate Unloading Step S70

Thereafter, the seal cap 219 is lowered by the boat elevator and the lower end of the process vessel 203 is opened. The boat 217 charged with the processed wafers 200 is unloaded from the process vessel 203 through the lower end of the process vessel 203 (boat unloading). The processed wafers 200 are then discharged from the boat 217 (wafer discharging). Thereby, the substrate processing according to the embodiment is completed.

### Other Embodiments

While the technique is described in detail by way of the embodiment, the above-described technique is not limited thereto. The above-described technique may be modified in various ways without departing from the gist thereof.

While the embodiment is described by way of an example wherein the wafer 200 having the polysilazane film is processed, the above-described technique is not limited thereto. The above-described technique may also be applied when a wafer having thereon a film containing a silazane bond (—Si—N—). The above-described technique may also be applied when a coating film including materials such as hexamethyldisilazane (HMDS), hexamethylcyclotrisilazane (HMCTS), polycarbosilazane and polyorganosilazane.

While the embodiment is described by way of an example wherein the wafer 200 having thereon a spin-coated and prebaked film containing a silazane bond is processed, the above-described technique is not limited thereto. The above-described technique may also be applied when oxidizing non-prebaked silicon-containing film formed by a CVD method from a silicon source such as monosilane (SiH₄) gas and trisilylamine (TSA) gas. Particularly, the non-prebaked silicon-containing film may be formed by a flowable CVD which enables the filling of the grooves with a high aspect ratio with the silicon-containing film. The silicon-containing film in the grooves may be subjected to an oxidation process or an annealing process according to the above-described technique.

According to the above-described embodiments, the substrate processing using a substrate processing apparatus having a vertical type process furnace is exemplified. However, the above-described technique is not limited thereto. The above-described technique may also be applied to the substrate processing using a single type substrate processing apparatus, a substrate processing apparatus having a hot wall type process furnace, a substrate processing apparatus having a cold wall type process furnace and a substrate processing apparatus capable of processing the wafers 200 by activating the process gas.

### Preferred Embodiments of Technique

Preferred embodiments of the technique will be supplementarily described below.

### Supplementary Note 1

According to one aspect of the technique described herein, there is provided a vaporizer including: a vaporization vessel constituted by a quartz body; and an atomizer made of a fluorine resin and configured to atomize a liquid source using a carrier gas and to supply the liquid source into the vaporization vessel.

### Supplementary Note 2

According to another aspect of the technique described herein, there is provided a substrate processing apparatus including: a process chamber where a substrate is processed; a vaporizer including: a vaporization vessel constituted by a quartz body; and an atomizer made of a fluorine resin and configured to atomize a liquid source using a carrier gas and to supply the liquid source into the vaporization vessel; and a gas pipe configured to supply a vaporized gas delivered by the vaporizer to the process chamber.

### Supplementary Note 3

According to still another aspect of the technique described herein, there is provided a method of manufacturing a semiconductor device, the method including: placing a substrate in a process chamber; atomizing a liquid source with a carrier gas by an atomizer made of a fluorine resin and configured to supply the liquid source into a vaporization vessel; vaporizing the liquid source in the vaporization vessel constituted by a quartz body to generate a vaporized gas; and supplying the vaporized gas to the substrate in the process chamber.

### Supplementary Note 4

According to still another aspect of the technique described herein, there is provided a method of assembling a vaporizer, the method comprising: connecting a vaporization vessel constituted by a quartz body and an atomizer made of a fluorine resin and configured to atomize a liquid source with a carrier gas and to supply the liquid source into the vaporization vessel by pressing the atomizer toward an end portion of the quartz body using an elastic body provided at an outside of the vaporizer.

According to the technique described herein, it is possible to prevent an occurrence of the metal contamination in a vaporizer for vaporizing a liquid source.

What is claimed is:

1. A vaporizer comprising:
a vaporization vessel constituted by a quartz body; and
an atomizer made of a fluorine resin and configured to atomize a liquid source using a carrier gas and to supply the liquid source into the vaporization vessel.

2. The vaporizer of claim 1, wherein the atomizer comprises a first block and a second block,
the first block is in contact with the vaporization vessel to seal its end portion and is provided with an ejection hole in a portion of the first block exposed to the inside of the vaporization vessel,
the second block overlaps with the first block and is provided with a nozzle configured to eject the liquid source toward the ejection hole of the first block,
a gap communicating with the ejection hole to introduce the carrier gas is provided between the first block and second block, and
the ejection hole and the nozzle are configured such that the carrier gas introduced into the gap is ejected via the ejection hole together with the liquid source ejected via the nozzle.

3. The vaporizer of claim 1, wherein the quartz body of the vaporization vessel is of cylindrical shape, and the atomizer is in contact with the quartz body to seal an end portion thereof and is connected to the vaporization vessel to close an opening portion thereof.

4. The vaporizer of claim 3, further comprising:
an elastic body attached to the atomizer and configured to press the atomizer toward the end portion of the quartz body.

5. The vaporizer of claim 2, further comprising:
an elastic body attached to the second block and configured to press the second block toward the first block and an end portion of the quartz body.

6. The vaporizer of claim 4, wherein one end portion of the elastic body is attached to a structure whose relative position with respect to the atomizer is fixed, and the other end portion of the elastic body is attached to the atomizer.

7. The vaporizer of claim 1, wherein a heater, a metal block and a heat transfer paste are arranged in order such that the quartz body, the heat transfer paste and the metal block are surrounded by the heat transfer paste, the metal block and the heater, respectively.

8. The vaporizer of claim 7, further comprising a spacer made of a heat-resistant rubber and provided between the quartz body and the metal block.

9. The vaporizer of claim 1, wherein the vaporization vessel comprises a first quartz body formed on a surface of an inner block and a second quartz body formed on a surface of an outer block, such that the first quartz body and the second quartz body constitutes a double tube structure, and
the inner block is configured to form a cylindrical gas flow path between the first quartz body and the second quartz body.

10. The vaporizer of claim 1, wherein the liquid source comprises hydrogen peroxide.

11. A substrate processing apparatus comprising:
a process chamber where a substrate is processed;
a vaporizer comprising:
a vaporization vessel constituted by a quartz body; and
an atomizer made of a fluorine resin and configured to atomize a liquid source using a carrier gas and to supply the liquid source into the vaporization vessel; and
a gas pipe configured to supply a vaporized gas delivered by the vaporizer to the process chamber.
